(19) United States
(12) Patent Application Publication
(10) Pub. No.: US 2014/0196760 A1
(43) Pub. Date: Jul. 17, 2014

(54) SOLAR CELL AND SOLAR MODULE

(71) Applicant: Sanyo Electric Co., Ltd., Osaka (JP)

(72) Inventor: Takahiro Mishima, Kobe-shi (JP)

(73) Assignee: Sanyo Electric Co., Ltd., Osaka (JP)

(21) Appl. No.: 14/210,498

(22) Filed: Mar. 14, 2014

Related U.S. Application Data
(63) Continuation of application No. PCT/JP2012/066731, filed on Jun. 29, 2012.

(30) Foreign Application Priority Data
Sep. 15, 2011 (JP) 2011-201641

(51) Int. Cl. H01L 31/05

(52) U.S. Cl. CPC H01L 31/05
USPC 136/244; 136/256

(57) ABSTRACT

A solar cell and a solar module are provided which have improved output characteristics. A solar cell (20) has a photovoltaic conversion unit (23), a first electrode (21), and a second electrode (22). The first electrode (21) and the second electrode (22) are arranged on one main surface of the photovoltaic conversion unit (23). The first electrode (21) has first finger portions (21a) and a first busbar portion (21b). The first finger portions (21a) extend in one direction. The first finger portions (21a) are connected electrically to the first busbar portion (21b). The width (W11) of the first busbar portion (21b) is smaller than the width (W21) of each first finger portion.

### CROSS-REFERENCE TO RELATED APPLICATIONS

This is a continuation of International Application PCT/JP2012/066731, with an international filing date of Jun. 29, 2012, filed by applicant, the disclosure of which is hereby incorporated by reference in its entirety.

### FIELD OF THE INVENTION

The present invention relates to a solar cell and a solar module.

### BACKGROUND

Back contact solar cells such as the ones described in Patent Document 1 are conventionally known. In a back contact solar cell, an electrode does not have to be provided on the light-receiving surface. As a result, improved output characteristics have been realized using back contact solar cells.

### PRIOR ART DOCUMENTS

### Patent Documents

Patent Document 1: Laid-Open Patent Publication No. 2010-80887

### SUMMARY

### Problem Solved by the Invention

In recent years, there has been growing demand for solar cells with even better output characteristics.

### Means of Solving the Problem

The solar cell of the present invention has a photovoltaic conversion unit, a first electrode, and a second electrode. The first electrode and the second electrode are arranged on one main surface of the photovoltaic conversion unit. The first electrode has a plurality of first finger portions and a first busbar portion. The first finger portions extend in one direction. The first finger portions are connected electrically to the first busbar portion. The width of the first busbar portion is smaller than the width of each first finger portion.

### Effect of the Invention

The present invention is able to provide a solar cell and a solar module with improved output characteristics.

### BRIEF DESCRIPTION OF THE DRAWINGS

FIG. 1 is a simplified cross-sectional view of the solar module in a first embodiment.

FIG. 2 is a simplified rear view of a solar cell in the first embodiment.

FIG. 3 is a simplified rear view of the solar cell string in the first embodiment.

FIG. 4 is a simplified rear view of a solar cell in a second embodiment.

### DETAILED DESCRIPTION

The following is an explanation of examples of preferred embodiments of the present invention. The following embodiments are merely examples. The present invention is not limited by the following embodiments in any way.

Further, in each of the drawings referenced in the embodiments, members having substantially the same function are denoted by the same symbols. The drawings referenced in the embodiments are also depicted schematically. The dimensional ratios of the objects depicted in the drawings may differ from those of the actual objects. The dimensional ratios of objects may also vary between drawings. The specific dimensional ratios of the objects should be determined with reference to the following explanation.

### 1st Embodiment

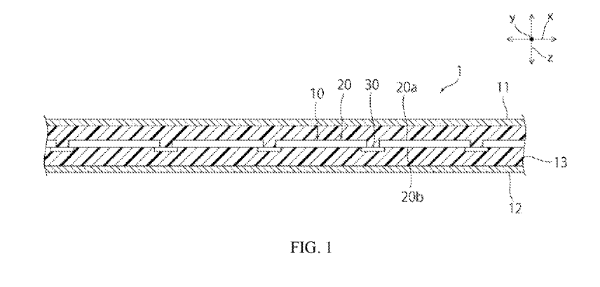

As shown in FIG. 1, the solar module 1 includes a solar cell string 10. The solar cell string 10 is arranged between a first protecting member 11 positioned on the light-receiving surface side, and a second protecting member 12 positioned on the back surface side. A bonding layer 13 is provided between the first protecting member 11 and the second protecting member 12. The solar cell string 10 is sealed by the bonding layer 13.

The first protecting member 11 can be composed of a translucent member such as a glass substrate or resin substrate. The second protecting member 12 can be composed of a glass substrate, or a resin substrate such as a resin sheet or a resin sheet containing interposed metal foil. The bonding layer 13 can be made of a resin such as an ethylene/vinyl acetate (EVA) copolymer, polyvinyl butyral (PVB), polyethylene (PE), or polyurethane (PU).

The solar cell string 10 includes a plurality of solar cells 20 arranged in the x-direction (the first direction). The solar cells 20 are connected electrically via a wiring member 30.

Each solar cell 20 has a first main surface 20a and a second main surface 20b. The solar cell 20 receives light primarily on the first main surface 20a. As a result, the first main surface 20a may be referred to as the light-receiving surface, and the second main surface 20b may be referred to as the back surface. The solar cell 20 may generate electricity only when light is received on the first main surface 20a constituting the light-receiving surface, or may be a bifacial solar cell which generates electricity when light is received on both the first main surface 20a and the second main surface 20b.

There are no particular restrictions on the type of solar cell 20 that is used. The solar cells 20 can be, for example, crystalline silicon solar cells using a crystalline silicon substrate.

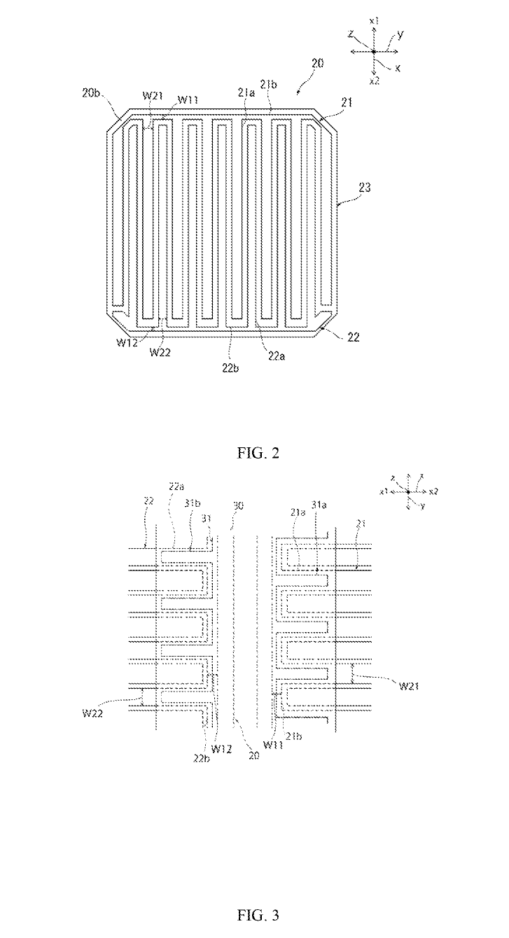

FIG. 2 is a simplified rear view of a solar cell 20. As shown in FIG. 2, the solar cell 20 has a first electrode 21 and a second electrode 22 on the second main surface 20b side. More specifically, the solar cell 20 has a photovoltaic conversion unit 23, and a first electrode 21 and a second electrode 22 arranged on the main surface on the back surface side of the photovoltaic conversion unit 23. One of the first electrode 21 or the second electrode 22 is the electrode used to collect electrons, and the other is the electrode used to collect holes.

Both the first electrode 21 and the second electrode 22 are comb-shaped. The first electrode 21 and the second electrode 22 are interdigitated. More specifically, the first electrode 21 and the second electrode 22 have a plurality of finger portions 21a, 22a, respectively. The finger portions 21a, 22a extend in one direction (the x-direction). The finger portions 21a, 22a are interdigitated at intervals in another direction (the y-direction which is orthogonal to the one direction (the x-direction).

The finger portions 21a are connected electrically to a busbar portion 21b. The busbar portion 21b is arranged on one side (the x1 side) of the finger portions 21a in the x-direction. The busbar portion 21b is provided on the x1 side of the solar cell 20 in the x-direction so as to extend from one end to the other in the y-direction.

Similarly, the finger portions 22a are connected electrically to a busbar portion 22b. The busbar portion 22b is arranged on the other side (the x2 side) of the finger portions 22a in the x-direction. The busbar portion 22b is provided on the x2 side of the solar cell 20 in the x-direction so as to extend from one end to the other in the y-direction.

As shown in FIG. 3, the first electrode 21 of one of two solar cells 20 adjacent to each other in the x-direction is connected electrically via a wiring member 30 to the second electrode 22 of the other solar cells 20. More particularly, the wiring member 30 has wiring 31. The wiring 31 has a first linear portion 31a which extends in the one direction (the x-direction), and a second linear portion 31b which also extends in the one direction (the x-direction) and is connected electrically to the first linear portion 31a. The first linear portion 31a is connected electrically to the finger portions 21a of the first electrode 21 of the solar cell 20 on the x2 side between the two solar cells 20 arranged adjacent to each other in the x-direction. The second linear portion 31b is connected electrically to the finger portions 22a of the second electrode 22 of the solar cell 20 on the x1 side between the two solar cells 20 arranged adjacent to each other in the x-direction.

The wiring member 30 and the solar cells 20 are bonded using an adhesive layer not shown in the drawings. The adhesive layer can be made of solder, a cured resin adhesive, or a cured resin adhesive containing a conductive material.

As shown in FIG. 2 and FIG. 3, the width W11 of the busbar portion 21b of the first electrode 21 is smaller than the width W21 of each finger portion 21a of the first electrode 21. In addition, the width W12 of the busbar portion 22b of the second electrode 22 is smaller than the width W22 of each finger portion 22a of the second electrode 22.

The width W11 of the busbar portion 21b is preferably no more than 0.95 times the width W21 of each finger portion 21a, and more preferably from 0.95 to 0.3 times the width. Also, the width W12 of the busbar portion 22b is preferably 0.95 times the width W22 of each finger portion 22a or less, and more preferably from 0.95 to 0.3 times the width.

Both the first electrode 21 and the second electrode 22 include a plated film. The plated film can be made of a metal such as Cu or Sn, or an alloy containing at least one of these metals. The thickness of the plated film can be from 2 μm to 50 μm.

The plated film can be formed using electrolytic plating. When the plated film is formed using electrolytic plating, an electrode rod is first pressed against the seed layer containing the conductive material formed in the photovoltaic conversion unit 23. The plated film is then formed by supplying electricity from the electrode rod to the seed layer in a plating solution. A thin plated film is formed where the electrode rod makes direct contact with the seed layer, forming a power supply pad (not shown in the drawing). A power supply pad is formed in both busbar portions 21b, 22b.

However, carriers such as holes and electrons are generated in the photovoltaic conversion unit 23 when the solar cell 20 is exposed to light. The carriers are collected by either the first electrode 21 or the second electrode 22. The photovoltaic conversion efficiency of a solar cell 20 is improved by suppressing loss due to the recombination of carriers.

In order to suppress the recombination of carriers, the distance the carriers generated in the photovoltaic conversion unit 23 have to travel through the photovoltaic conversion unit 23 to be collected by the first electrode 21 or the second electrode 22 should be as short as possible. As a result, the first electrode and the second electrode require a fine pattern. For this reason, the width of the finger portions is generally minimized. However, the width of the busbar portion is usually not as small as the width of the finger portions. This is because there is a chance that the photovoltaic conversion efficiency will decline if the electrical resistance of the busbar portion collecting the carriers from the finger portions is too high. When a portion of the electrodes is composed of plated film, the plated film is believed to help keep the busbar portions from becoming as thin as the finger portions, even when several areas are formed in the busbar portions as power supply points, and the busbar portions are formed in accordance with the width of the power supply points.

However, when the busbar portions are thick, some of the carriers generated in the area of the photovoltaic conversion unit beneath the busbar portions are not collected by the busbar portions and have to travel a long distance to be collected by the electrodes. This may cause the photovoltaic conversion efficiency to decline.

In order to address this, the width W11 of the busbar portion 21b of the first electrode 21 in the solar cell 20 is smaller than the width W21 of each finger portion 21a. The width W12 of the busbar portion 22b of the second electrode 22 is also smaller than the width W22 of each finger portion 22a. This can suppress loss due to the recombination of carriers generated in the area of the photovoltaic conversion unit 23 beneath the busbar portions 21b, 22b. As a result, improved photovoltaic conversion efficiency can be realized.

From the standpoint of realizing improved photovoltaic conversion efficiency, the width W11 of the busbar portion 21b is preferably 0.95 times the width W21 of each finger portion 21a or less. Also, the width W12 of the busbar portion 22b is preferably 0.95 times the width W22 of each finger portion 22a or less. However, when the width of the busbar portions 21b, 22b is too small, problems occur related to the supply of power when forming the plated film, and plated film sometimes cannot be formed. Therefore, the width W11, W12 of the busbar portions 21b, 22b is preferably 0.1 times the width W21, W22 of the finger portions 21a, 22a or greater, and more preferably 0.3 times or greater.

Also, as shown in FIG. 3, the wiring members 30 in the solar module 1 are connected to the finger portions 21a, 22a, which are thicker than the busbar portions 21b, 22b. This can suppress the decline in photovoltaic conversion efficiency caused by resistance loss in the electrodes 21, 22 better than a situation in which the wiring members are connected electrically to the thin busbar portions. As a result, even better photovoltaic conversion efficiency can be realized.

The following is an explanation of another example of a preferred embodiment of the present invention. In the following explanation, members having substantially the same functions as those in the first embodiment are denoted by the same reference numbers, and further explanation of these members has been omitted.

### 2nd Embodiment

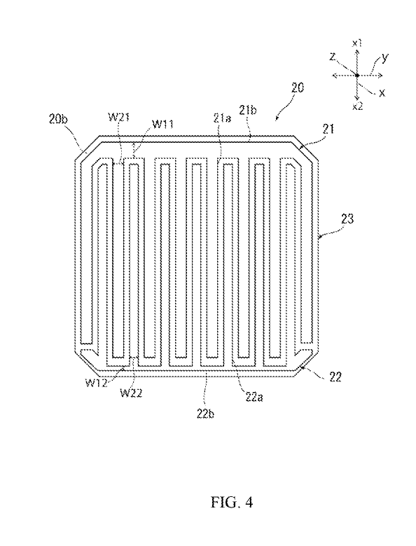

In the explanation of the example in the first embodiment, the widths W11, W12 of the busbar portions 21b, 22b of the first and second electrodes 21, 22 were both smaller than the widths W21, W22 of the finger portions 21a, 22a. However, the present invention is not limited to this configuration. In this embodiment, as shown in FIG. 4, the width W11 of the busbar portion 21b of the first electrode 21 is greater than the width W21 of each finger portion 21a, and the width W12 of the busbar portion 22b of the second electrode 22 is smaller than the width W22 of each finger portion 22a. This embodiment is able to suppress loss due to the recombination of carriers, and can realize an improvement in photovoltaic conversion efficiency similar to that of the first embodiment.

When the width of the busbar portion is smaller than the width of each finger portion in only one of the first and second electrodes 21, 22, the electrode with the thinner busbar portion is preferably the electrode used to collect the majority carrier. In other words, in the present embodiment, the first electrode 21 is preferably the electrode used to collect the majority carrier. In this situation, the minority carrier generated in the area of the photovoltaic conversion unit 23 beneath the busbar portion 21b has to travel a shorter distance to be collected by the second electrode 22. This can suppress loss due to the recombination of minority carriers. The resulting improvement in photovoltaic conversion efficiency is thus better than a situation in which the busbar portion of the electrode collecting the minority carrier is thinner than the finger portions and loss due to the recombination of the majority carrier is suppressed.

The present invention includes many other embodiments not described herein. Therefore, the technical scope of the present invention is defined solely by the items of the invention specified in the claims pertinent to the above explanation.

### KEY TO THE DRAWINGS

1: Solar module

20: Solar cell

21: 1st electrode

22: 2nd electrode

21a, 22a: Finger portions

21b, 22b: Busbar portions

23: Photovoltaic conversion unit

30: Wiring member

What is claimed is:

1. A solar cell having a photovoltaic conversion unit, and a first electrode and a second electrode arranged on the same main surface of the photovoltaic conversion unit,
the first electrode having a plurality of finger portions extending in one direction, and a first busbar portion connected electrically to the plurality of first finger portions, and
the width of the first busbar portion being smaller than the width of first finger portion.

2. The solar cell according to claim 1, wherein the width of the first busbar portion is no more than 0.95 times the width of first finger portion.

3. The solar cell according to claim 1, wherein the first electrode is the electrode used to collect the majority carrier.

4. The solar cell according to claim 1, wherein the first electrode includes a plated film.

5. The solar cell according to claim 1, wherein the second electrode has a plurality of second finger portions extending in the one direction, and a second busbar portion connected electrically to the plurality of second finger portions,
the width of the second busbar portion being smaller than the width of second finger portion.

6. A solar module comprising:
a plurality of solar cells each having a photovoltaic conversion unit, and a first electrode and a second electrode arranged on the same main surface of the photovoltaic conversion unit, and
a wiring member electrically connecting the plurality of solar cells;
the first electrode having a plurality of finger portions extending in one direction, and a first busbar portion connected electrically to the plurality of first finger portions, and
the width of the first busbar portion being smaller than the width of first finger portion.

7. The solar module according to claim 6, wherein the wiring member is connected electrically to the first electrode in the first finger portions.
